(19) United States
(12) Patent Application Publication
(10) Pub. No.: US 2021/0328188 A1
(43) Pub. Date: Oct. 21, 2021

(54) DISPLAY COMPONENT PACKAGING ASSEMBLY, MANUFACTURING METHOD THEREOF, AND DISPLAY APPARATUS

(71) Applicants: BEIJING BOE DISPLAY TECHNOLOGY CO., LTD., Beijing (CN); BOE TECHNOLOGY GROUP CO., LTD., Beijing (CN)

(72) Inventors: Jinyu REN, Beijing (CN); Yongzhi SONG, Beijing (CN); Guojing MA, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 16/344,014

(22) PCT Filed: Dec. 3, 2018
(86) PCT No.: PCT/CN2018/118943

§ 371 Date: Apr. 22, 2019

(30) Foreign Application Priority Data
Dec. 15, 2017 (CN) 201711354148.5

(51) Int. Cl. H01L 51/52; H01L 51/56

(52) U.S. Cl. CPC H01L 51/5259; H01L 51/56; H01L 51/5253

(57) ABSTRACT

A packaging assembly for packaging a display component over a substrate in a display apparatus includes a first super absorbent polymer layer covering the display component and configured to absorb water from the display component, which can be a starch-type super absorbent polymer, a cellulose-type super absorbent polymer, or a synthetic-type super absorbent polymer The first super absorbent polymer layer can be included in a first packaging sub-assembly, which further includes a first inorganic film layer, a first organic film layer, and a second organic film layer. The first inorganic film layer covers the outside of the display component, the first organic film layer covers an outside of the first inorganic film layer, the first super absorbent polymer layer covers an outside of the first organic film layer, and the second organic film layer covers an outside of the first super absorbent polymer layer.

### CROSS-REFERENCE TO RELATED APPLICATION

The present application claims priority to Chinese Patent Application No. CN 201711354148.5 filed on Dec. 15, 2017, the disclosure of which is hereby incorporated by reference in its entirety.

### TECHNICAL FIELD

The present disclosure relates generally to the field of display technologies, specifically to a display component packaging technology, and more specifically to a display component packaging assembly, its manufacturing method, and a display apparatus containing the display component packaging assembly.

### BACKGROUND

Due to the advantages such as self-luminescence, high brightness, high contrast, low working voltage, flexible display, etc., the organic light-emitting diode (OLED) display technologies have been regarded as the most promising display technologies in current times.

However, some factors or components in the ambient/environment of an OLED display device, such as water and oxygen in the air, have negative influences on the working life of the OLED display device. Therefore, a packaging structure is typically required to encapsulate the OLED display device so that the OLED display device can be isolated from the ambient, and the working life of the OLED display device can be prolonged.

### SUMMARY

In a first aspect, the present disclosure provides a packaging assembly for packaging a display component over a substrate.

The packaging assembly comprises a first super absorbent polymer layer, which is arranged to cover the display component and is configured to absorb water from the display component to thereby ensure a waterproofness thereof.

According to some embodiments, the first super absorbent polymer layer is included in a first packaging sub-assembly, and the first packaging sub-assembly further comprises a first inorganic film layer, a first organic film layer, and a second organic film layer. The first inorganic film layer is arranged to cover the outside of the display component; the first organic film layer is arranged to cover an outside of the first inorganic film layer; the first super absorbent polymer layer is arranged to cover an outside of the first organic film layer; and the second organic film layer is arranged to cover an outside of the first super absorbent polymer layer.

Optionally, the packaging assembly can further include a second inorganic film layer, which is arranged over the first packaging sub-assembly.

Further optionally, the packaging assembly can further include a second packaging sub-assembly over the first packaging sub-assembly, and the second packaging sub-assembly can comprise a second inorganic film layer, a third organic film layer, a second super absorbent polymer layer, and a fourth organic film layer. The second inorganic film layer is arranged to cover an outside of the second organic film layer; the third organic film layer is arranged to cover an outside of the second inorganic film layer; the second super absorbent polymer layer is arranged to cover an outside of the third organic film layer; and the fourth organic film layer is arranged to cover an outside of the second super absorbent polymer layer.

Further optionally, the packaging assembly can further include at least one second inorganic film layer and at least one third organic film layer, which are alternately arranged over the first packaging sub-assembly.

In any one embodiment of the packaging assembly described above, the first super absorbent polymer layer can optionally comprise at least one of a starch-type super absorbent polymer, a cellulose-type super absorbent polymer, or a synthetic-type super absorbent polymer.

According to some embodiments of the packaging assembly, the first super absorbent polymer layer comprises a synthetic-type super absorbent polymer, and the synthetic-type super absorbent polymer is polyacrylamide polymer (PAMA).

According to some other embodiments of the packaging assembly, the first super absorbent polymer layer comprises at least one of a starch-acrylonitrile polymer or a cellulose acrylonitrile polymer.

In embodiments of the packaging assembly, the second organic film layer can optionally comprise at least one of polymethyl methacrylate (PMMA) or polycarbonate (PC).

In a second aspect, the present disclosure further provides a display apparatus.

The display apparatus comprises a substrate, a display component over the substrate, and a packaging assembly. The packaging assembly can be based on any one of the embodiments of the packaging assembly described above, and the packaging assembly is arranged over, and configured to cover the display component.

According to some embodiments of the display apparatus, the display component comprises an OLED display component.

In a third aspect, the present disclosure further provides a method for manufacturing a packaging assembly.

The method comprises the following steps:

providing a display component over a substrate; and

forming a first packaging sub-assembly over the display component.

Herein, the first packaging sub-assembly comprises a first super absorbent polymer layer arranged to cover the display component and configured to absorb water from the display component to thereby ensure a waterproofness thereof.

Optionally in the method described above, the first packaging sub-assembly further comprises a first inorganic film layer, a first organic film layer, and a second organic film layer. As such, the step of forming a first packaging sub-assembly over the display component comprises the following sub-steps:

forming a first inorganic film layer over the display component;

forming a first organic film layer over the first inorganic film layer; and

forming the first super absorbent polymer layer and a second organic film layer sequentially over the first organic film layer.

Optionally in the method described above, the first packaging sub-assembly can further include a first inorganic film layer, a first organic film layer, and a second organic film layer, and the step of forming a first packaging sub-assembly over the display component accordingly comprises:

preparing a mixture solution comprising first components for synthesizing the first super absorbent polymer layer and second components for synthesizing the second organic film layer;

coating the mixture solution over the first organic film layer;

applying a first reaction condition to the mixture solution such that the first super absorbent polymer layer is formed over the first organic film layer; and

applying a second reaction condition to the mixture solution such that the second organic film layer is formed over the first super absorbent polymer layer.

Herein, in the sub-step of preparing a mixture solution comprising first components for synthesizing the first super absorbent polymer layer and second components for synthesizing the second organic film layer, the first components for synthesizing the first super absorbent polymer layer can optionally comprise acrylamide (AM), 2-acrylamide-2-methyl propane sulfonic acid (AMPS), N, N′-methylene diacrylamide (NMBA), and potassium persulfate (KPS).

Further optionally, in the sub-step of preparing a mixture solution comprising first components for synthesizing the first super absorbent polymer layer and second components for synthesizing the second organic film layer, a mass ratio of acrylamide (AM), 2-acrylamide-2-methyl propane sulfonic acid (AMPS), and N, N′-methylene diacrylamide (NMBA) in the mixture solution can be around 25:75:0.01. Furthermore, in the sub-step of applying a first reaction condition to the mixture solution such that the first super absorbent polymer layer is formed over the first organic film layer, the first reaction condition can comprise a pH of around 2.0, a temperature of around 40±5° C.

Further optionally, in the sub-step of applying a first reaction condition to the mixture solution such that the first super absorbent polymer layer is formed over the first organic film layer, the first reaction condition can further comprise an induction condition comprising at least one of ultrasonic induction, photonic induction, or chemical induction.

According to some embodiments of the method described above, in the sub-step of preparing a mixture solution comprising first components for synthesizing the first super absorbent polymer layer and second components for synthesizing the second organic film layer, the second components for synthesizing the second organic film layer can comprise methyl methacrylate and azobisisobutyronitrile (AIBN).

Herein, optionally, in the sub-step of preparing a mixture solution comprising first components for synthesizing the first super absorbent polymer layer and second components for synthesizing the second organic film layer, a mass ratio of methyl methacrylate and azobisisobutyronitrile (AIBN) in the mixture solution can be around 99.5:0.5, and in the sub-step of applying a second reaction condition to the mixture solution such that the second organic film layer is formed over the first super absorbent polymer layer, the second reaction condition can comprise a pH of around 7.0 and a temperature of around 70-80° C.

According to some embodiments of the method, the sub-step of forming the first super absorbent polymer layer and a second organic film layer sequentially over the first organic film layer can comprises:

forming the first super absorbent polymer layer over the first organic film layer; and

forming the second organic film layer sequentially over the first super absorbent polymer layer.

Other embodiments of the packaging assembly, the display apparatus, and the method for manufacturing a packaging assembly can become obvious to people of ordinary skill in the art in light of the embodiments provided above.

### BRIEF DESCRIPTION OF DRAWINGS

In order to clearly illustrate the various embodiments provided in the present disclosure, the following are drawings that accompany the description of the embodiments.

It is noted that these drawings shall be interpreted to serve illustrating purposes only, and that these drawings may represent just some, but not all, of embodiments of the present disclosure. For those skilled in the art, other embodiments that are based on the structures as described below and illustrated in these drawings may become obvious. As such, these other embodiments shall be interpreted to be contained within the scope of the disclosure.

FIG. 1 illustrates the structure of a display component packaging assembly typically employed in an existing OLED display apparatus.

FIG. 2 illustrates a schematic structure of a display component packaging assembly according to some embodiments of the disclosure;

FIG. 3 illustrates a schematic structure of the display component packaging assembly according to some other embodiments of the disclosure;

FIG. 4 illustrates a schematic structure of the display component packaging assembly according to yet some other embodiments of the disclosure;

FIG. 5 illustrates a schematic structure of the display component packaging assembly according to yet some other embodiments of the disclosure;

FIG. 6 is a flow chart of a method for manufacturing a display component packaging assembly;

FIG. 7 is a flow chart of the step S200 of the method as illustrated in FIG. 6 according to some embodiments of the disclosure;

FIG. 8A is a flow chart of the sub-step S230 in the step S200 of the method as illustrated in FIG. 7 according to some embodiments of the disclosure;

FIG. 8B is a flow chart of the sub-step S230 in the step S200 of the method as illustrated in FIG. 7 according to some other embodiments of the disclosure; and

FIG. 9 is a flow chart of one specific embodiment of the sub-step S230 in the step S200 of the method as illustrated in FIG. 7.

### DETAILED DESCRIPTION

Various embodiments of the present disclosure are described below with specific examples, and other advantages and effects of the present disclosure can be easily understood by those skilled in the field of technology from the contents disclosed in this specification.

Apparently, the described embodiments are only a part of embodiments in the present disclosure, rather than all of them. The present disclosure can also be implemented or applied through different specific embodiments, and various details of the specification can also be modified or changed based on different viewpoints and applications without departing from the spirit of the present disclosure.

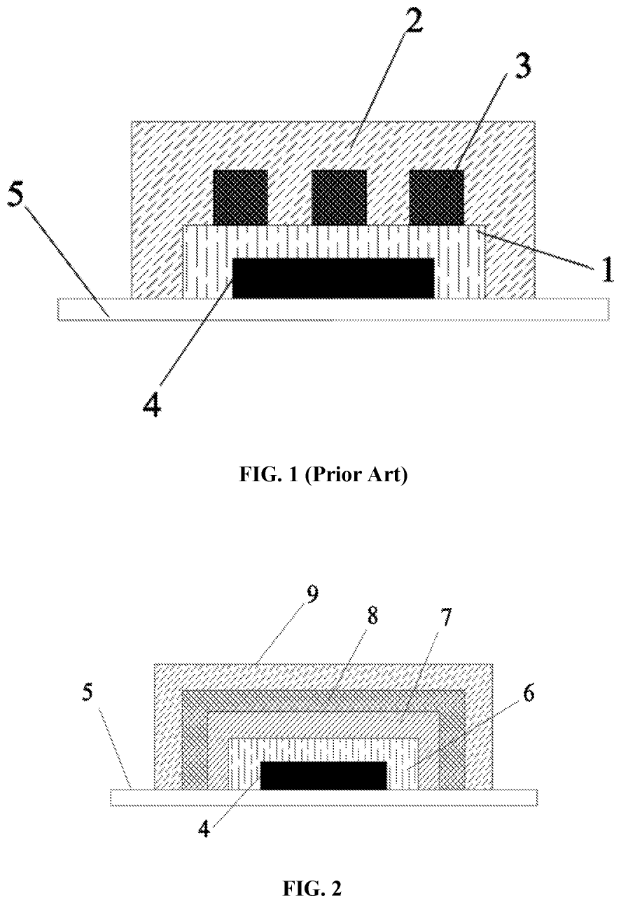

In existing OLED packaging technologies, a package assembly for an OLED display panel (i.e. termed as OLED package assembly hereafter) typically includes an inorganic film layer 1 and an organic film layer 2, which are arranged sequentially over an outside of an OLED component 4 on a substrate 5, as illustrated in FIG. 1. A desiccant layer 3 is commonly arranged between the organic film layer 2 and the inorganic film layer 1. Typically, the desiccant layer 3 is arranged in a pattern of separated dots or lines that are disposed in between the organic film layer 2 and the inorganic film layer 1. The desiccant layer 3 often has a composition of an inorganic substance such as CaO, BaO, etc.

However, the following issues or problems are commonly observed in the existing OLED packaging technology as described above.

Firstly, the desiccant layer 3 is arranged in a pattern of separated dots or lines that are disposed in between the organic film layer 2 and the inorganic film layer 1, which can thus increase the unevenness of the various packaging film layers, commonly resulting in the presence of defects between the organic film layer 2 and the inorganic film layer 1, in turn negatively influencing the airtightness of each or both of the organic film layer 2 and the inorganic film layer 1.

Secondly, because each individual desiccant dot or desiccant line in the desiccant layer 3 is independent from, or separated from one another, they have different expansion rates after water absorption, causing that different regions of each layer have different extents of deformations, which in turn can produce stresses, commonly leading to damages to the packaging film layers.

Finally, due to the characteristics of the inorganic substance (e.g. CaO, BaO, etc.) employed as the composition for the desiccant layer 3, each of these inorganic substances has a relatively low bonding force with each of the organic film layer 2 or the inorganic film layer 1, which causes that each of the organic film layer 2 or the inorganic film layer 1 is easily peeled off, in turn negatively affecting the packaging effect.

In order to address the above issues associated with the existing OLED packaging technology, the present disclosure provides a display component packaging assembly for a display component (i.e. display component packaging assembly). The display component packaging assembly comprises at least one packaging sub-assembly, which is arranged over, and configured to cover an outside of, a display component over a substrate.

FIG. 2 illustrates a schematic structure of the display component packaging assembly according to some embodiments of the disclosure. As shown in FIG. 2, the display component packaging assembly substantially consists of one packaging sub-assembly, and the one packaging sub-assembly comprises a first inorganic film layer 6, and a first organic film layer 7, which are sequentially arranged to cover, and thereby configured to package, a display component 4 over a substrate 5.

In order to increase the waterproofness and the antioxidation of the display component packaging assembly, the one packaging sub-assembly in the above embodiments of the display component packaging assembly further comprises a super absorbent polymer (SAP) layer 8 and a second organic film layer 9, which are sequentially arranged to cover the first organic film layer 7.

Herein the super absorbent polymer layer 8 is arranged between the first organic film layer 7 and the second organic film layer 9 and is configured to absorb the water in the display component packaging assembly. As such, the display component packaging assembly has a relatively good tightness including an improved airtightness, waterproofness, and/or antioxidation.

In addition, the super absorbent polymer layer 8 is arranged to evenly cover the first organic film layer 7 and is further configured to have a relatively even thickness. As such, the flatness of the display component packaging assembly can be realized, and the tightness (waterproofness, airtightness, and/or antioxidation) of the display component packaging assembly can also be improved.

Furthermore, the super absorbent polymer layer 8 has a relatively even expansion rates after water absorption, which can effectively avoid the production of stresses that are easily produced in the desiccant layer 3 in existing OLED packaging technology.

Finally, the super absorbent polymer layer 8 has an additional advantage of having a relatively high bonding force with at least the first organic film layer 7, which can effectively avoid the peeling off of the super absorbent polymer layer 8 from the first organic film layer 7.

Optionally, the super absorbent polymer layer 8 can have a composition of a super-absorbent resin polymer. For example, the super absorbent polymer layer 8 can have a composition of a starch-type super absorbent polymer, such as a starch-acrylonitrile polymer. The super absorbent polymer layer 8 can also have a composition of a cellulose-type super absorbent polymer, such as a cellulose acrylonitrile polymer. The super absorbent polymer layer 8 can also have a composition of a synthetic super absorbent polymer, such as a polyacrylamide polymer (PAMA).

In addition to the above mentioned embodiments illustrated in FIG. 2 where display component packaging assembly comprises only one packaging sub-assembly, according to some other embodiments of the disclosure, the display component packaging assembly can include more than one packaging sub-assembly. Each of the more than one packaging sub-assembly can have a basic structure of the embodiments of the display component packaging assembly described above and illustrated in FIG. 2. In these embodiments of the display component packaging assembly, the more than one packaging sub-assembly are arranged sequentially to cover an outside the display component 4 on the substrate 5 in order to further increase the tightness of the display component packaging assembly.

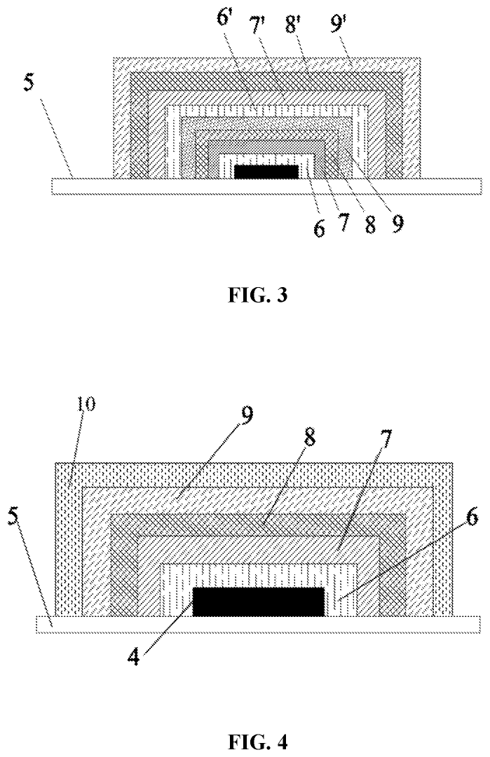

In the embodiments of the display component packaging assembly illustrated in FIG. 3, a total of two packaging sub-assemblies are arranged outside, and configured to cover, the display component 4 on the substrate 5. To be more specific, the display component packaging assembly consists of a first packaging sub-assembly and a second packaging sub-assembly, sequentially over the display component 4.

The first packaging sub-assembly comprises a first inorganic film layer 6, a first organic film layer 7, a super absorbent polymer layer 8, and a second organic film layer 9, arranged sequentially to cover the display component 4 over the substrate 5. The second packaging sub-assembly is disposed over, and arranged to cover, the first packaging sub-assembly, and comprises another first inorganic film layer 6′, another first organic film layer 7′, another super absorbent polymer layer 8′, and another second organic film layer 9′.

According to some other embodiments, in addition to the at least one packaging sub-assembly that are arranged to cover the display component on the substrate, the display component packaging assembly can further include other film layers arranged outside, and configured to cover the at least one packaging sub-assembly. These other film layers can include at least one inorganic film layers, at least one organic film layers, or at least one set of alternately arranged inorganic film layer and organic film layer.

FIG. 4 illustrates one such embodiment of the display component packaging assembly. As shown in FIG. 4, in addition to one packaging sub-assembly comprising a first inorganic film layer 6, a first organic film layer 7, a super absorbent polymer layer 8, and a second organic film layer 9, which are arranged sequentially to cover the display component 4 over the substrate 5, the display component packaging assembly further includes a second inorganic film layer 10, which is arranged over, and configured to cover the second organic film layer 9.

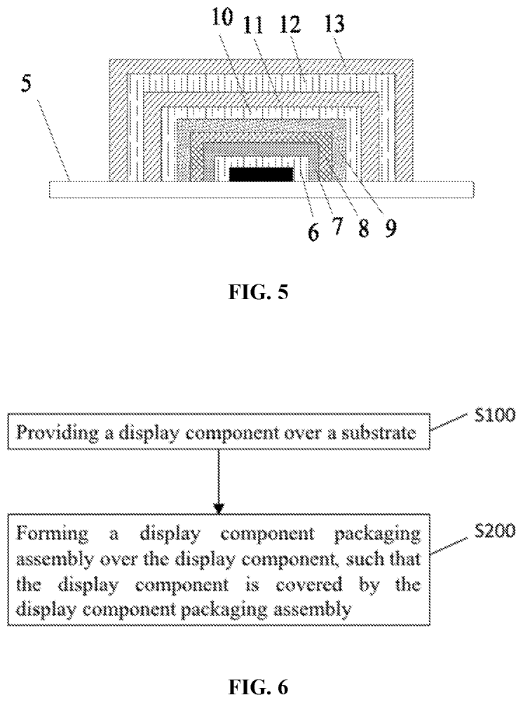

FIG. 5 illustrates another embodiment of the display component packaging assembly. As shown in FIG. 5, in addition to one packaging sub-assembly comprising a first inorganic film layer 6, a first organic film layer 7, a super absorbent polymer layer 8, and a second organic film layer 9, which are arranged sequentially to cover the display component 4 over the substrate 5, the display component packaging assembly further includes two sets of alternately arranged inorganic film layer and organic film layer including a second inorganic film layer 10, a third organic film layer 11, a third inorganic film layer 12, a fourth organic film layer 13.

The following are noted for any of the embodiments of the display component packaging assembly as described above and illustrated in FIGS. 2-5.

Firstly, in any of the above mentioned embodiments of the display component packaging assembly, the display component 4 can be an OLED component, but can be of other types. The display component 4 is disposed over a substrate 5.

Secondly, in any of the above embodiments described above, the first inorganic film layer in each of the at least one packaging sub-assembly, or each of the at least one inorganic film layer outside the at least one packaging sub-assembly, can have a composition of silicon nitride (SiNₓ), silicon dioxide (SiO₂), but can have a different composition.

Thirdly, in any of the above embodiments described above, the first organic film layer or the second organic film layer in each of the at least one packaging sub-assembly, or each of the at least one organic film layer outside the at least one packaging sub-assembly can have a composition of polymethyl methacrylate (PMMA) or polycarbonate (PC), but can have a different composition.

In a second aspect, the present disclosure further provides a display apparatus, which includes a display component packaging assembly according to any one of the embodiments as described above and illustrated in FIGS. 2-5. Herein the display apparatus can be an OLED display apparatus, but can also be of another type.

In a third aspect, the present disclosure further provides a method for manufacturing a display component packaging assembly, which is substantially a method for packaging a display component.

Specifically, as illustrated in FIG. 6, the method comprises the following steps:

S100: providing a display component 4 over a substrate 5; and

S200: forming a display component packaging assembly over the display component 4, such that the display component 4 is covered by the display component packaging assembly.

Herein the display component packaging assembly can be based on any one of the embodiments of the display component packaging assembly having a structure described above and illustrated in FIGS. 2-5.

Specifically, the display component packaging assembly comprises a first packaging sub-assembly disposed to directly cover the display component 4. The first packaging sub-assembly comprises a first inorganic film layer 6, a first organic film layer 7, a super absorbent polymer layer 8, and a second organic film layer 9, which are sequentially arranged over the display component 4.

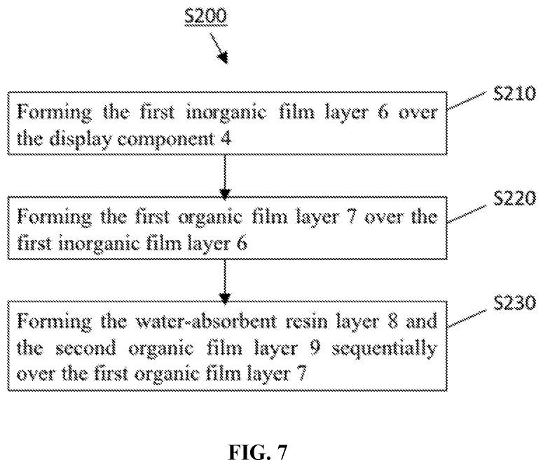

As such, the step S200 of the method comprises a step of forming the first packaging sub-assembly over the display component 4 on the substrate 5. Specifically, the step comprises the following sub-steps, as illustrated in FIG. 7.

S210: forming the first inorganic film layer 6 over the display component 4;

S220: forming the first organic film layer 7 over the first inorganic film layer 6; and

S230: forming the super absorbent polymer layer 8 and the second organic film layer 9 sequentially over the first organic film layer 7.

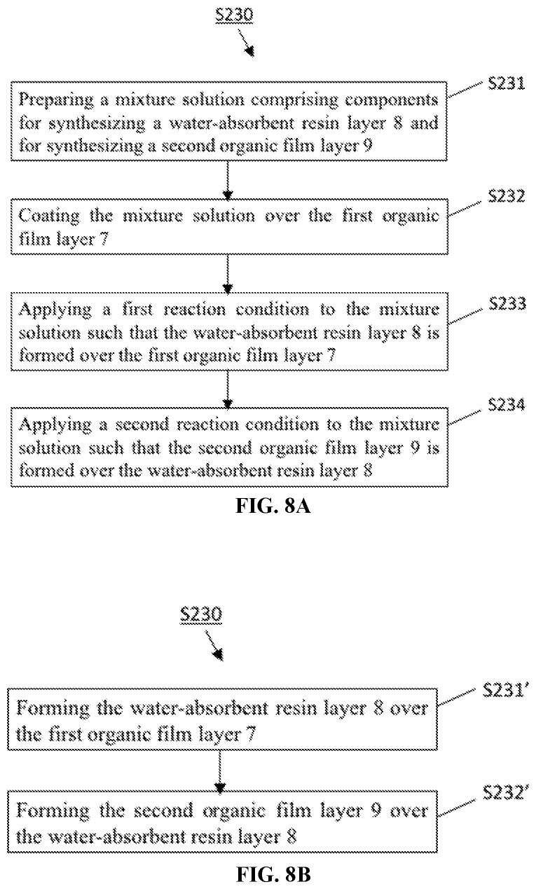

According to some embodiments of the method illustrated in FIG. 8A, the sub-step S230 can involve the preparation of a mixture solution comprising components for synthesizing the super absorbent polymer layer 8 and for synthesizing the second organic film layer 9, and the application of two different reaction conditions for the sequential formation of the super absorbent polymer layer 8 and the second organic film layer 9.

As such, the sub-step S230 comprises the following sub-steps S231-S234:

S231: preparing a mixture solution comprising first components for synthesizing a super absorbent polymer layer 8 and second components for synthesizing a second organic film layer 9;

S232: coating the mixture solution over the first organic film layer 7;

S233: applying a first reaction condition to the mixture solution such that the super absorbent polymer layer 8 is formed over the first organic film layer 7; and

S234: applying a second reaction condition to the mixture solution such that the second organic film layer 9 is formed over the super absorbent polymer layer 8.

It is noted that there are multiple manners for forming the super absorbent polymer layer 8 and the second organic film layer 9, as long as the first reaction condition for synthesizing the super absorbent polymer layer 8 and the second reaction condition for synthesizing the second organic film layer 9 are different to thereby allow the separate and sequential formation of the super absorbent polymer layer 8 and the second organic film layer 9.

Herein, the super absorbent polymer layer 8 can be formed via a polymerization reaction of super absorbent polymer monomers. For example, the first reaction condition for forming the super absorbent polymer layer 8 can be a polymerization reaction occurring in a reaction that contains resin monomers including acrylamide (AM) and 2-acrylamide-2-methylpropyl sulfonic acid (AMPS), a crosslinker of N, N′-methylene diacrylamide (NMBA), and an initiator potassium persulfate (KPS). Herein the mass ratio of AM:AMPS:NMBA can be around 25:75:0.01. The polymerization reaction can be induced by ultrasonic vibration.

It is noted that other reaction conditions are also possible for the first reaction condition to form the super absorbent polymer layer 8. For example, the reaction can include other types of resin monomers, crosslinkers, and initiators, and can be induced by other conditions such as ultrasonic induction, photonic induction, or chemical induction, etc. There are no limitations herein.

Optionally, the first inorganic film layer 6 can have a composition of silicon nitride (SiNₓ) or silicon dioxide (SiO₂). Each of the first organic film layer 7 and the second organic film layer 9 can have a composition of polymethyl methacrylate (PMMA) or polycarbonate (PC).

In addition, each of the first organic film layer 7 and the second organic film layer 9 can be synthesized by reactions using organic monomers and initiators. For example, in some embodiments of the display component packaging assembly in the display apparatus, the first organic film layer 7 comprises a layer of polymethyl methacrylate (PMMA), it can be synthesized by a reaction using methyl methacrylate as a monomer and azobisisobutyronitrile (AIBN) as an initiator. The mass ratio of the methyl methacrylate and azobisisobutyronitrile (AIBN) can be 99.5:0.5.

It is noted that compositions other than the compositions as described above can also be employed as the material for each of the first inorganic film layer 6, the first organic film layer 7, and the second organic film layer 9. The description of these compositions and the synthesis reactions thereof is skipped herein.

It is further noted that in addition the above embodiment of the sub-step S230 illustrated in FIG. 8A, according to some other embodiments illustrated in FIG. 8B, the sub-step S230 can include two separate sub-steps to sequentially form the super absorbent polymer layer 8 and the second organic film layer 9:

S231′: forming the super absorbent polymer layer 8 over the first organic film layer 7; and

S232′: forming the second organic film layer 9 over the super absorbent polymer layer 8.

Herein in the embodiments illustrated in FIG. 8B, the sub-step S231′ can include a polymerization reaction over super absorbent polymer monomers as described above, and the sub-step S232′ can include a polymerization reaction over organic monomers and initiators as described above.

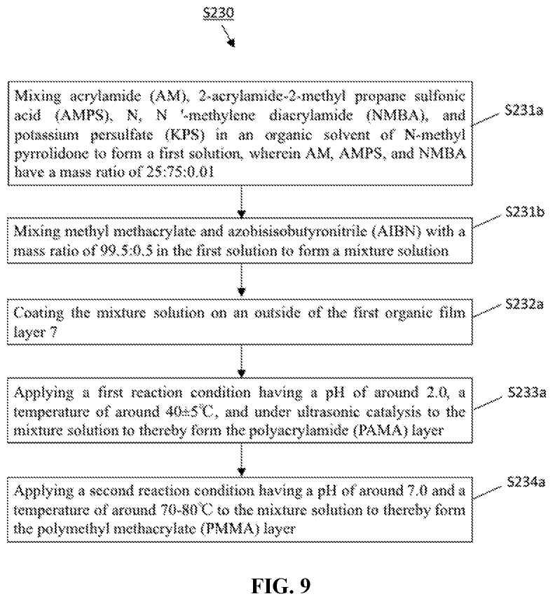

In the following, a specific embodiment of a method for manufacturing a display component packaging assembly for an OLED display apparatus is described below and illustrated in FIG. 9. Here in this illustrating embodiment, the super absorbent polymer layer 8 comprises a polyacrylamide (PAMA) layer, and the second organic film layer 9 comprises a polymethyl methacrylate (PMMA) layer, and the sub-step S231 as described above and illustrated in FIG. 8A specifically includes the following specific steps.

S231a: mixing acrylamide (AM), 2-acrylamide-2-methyl propane sulfonic acid (AMPS), N, N′-methylene diacrylamide (NMBA), and potassium persulfate (KPS) in an organic solvent of N-methyl pyrrolidone to form a first solution, wherein AM, AMPS, and NMBA have a mass ratio of 25:75:0.01;

S231b: mixing methyl methacrylate and azobisisobutyronitrile (AIBN) with a mass ratio of 99.5:0.5 in the first solution to form a mixture solution.

In the mixture solution, because each of acrylamide (AM), 2-acrylamide-2-methyl propane sulfonic acid (AMPS), N, N′-methylene diacrylamide (NMBA), and potassium persulfate (KPS) is hydrophilic, whereas each of methyl methacrylate and azobisisobutyronitrile (AIBN) is hydrophobic, these above components in the organic solvent of N-methyl pyrrolidone will be separated to form two layers including a lower layer and an upper layer.

Because the components for synthesizing the polyacrylamide (PAMA) layer (i.e. acrylamide (AM), 2-acrylamide-2-methyl propane sulfonic acid (AMPS), N, N′-methylene diacrylamide (NMBA), and potassium persulfate (KPS)) have relatively higher average molecular mass, they are in the lower layer; because the components for synthesizing the polymethyl methacrylate (PMMA) layer (i.e. methyl methacrylate and azobisisobutyronitrile (AIBN)) have relatively lower average molecular mass, they are in the upper layer.

After S231b, the sub-step S232 specifically includes:

S232a: coating the mixture solution on an outside of the first organic film layer 7.

Following S232, the sub-step S233 specifically includes:

S233a: applying a first reaction condition having a pH of around 2.0, a temperature of around 40±5° C., and under ultrasonic catalysis to the mixture solution to thereby form the polyacrylamide (PAMA) layer;

Following S233, the sub-step S234 specifically includes:

S234a: applying a second reaction condition having a pH of around 7.0 and a temperature of around 70-80° C. to the mixture solution to thereby form the polymethyl methacrylate (PMMA) layer.

As such, through the above sub-steps S231a, 231b, 232, 233, and 234, the super absorbent polymer layer 8 and the second organic film layer 9 can be sequentially formed on an outside of the first organic film layer 7.

It is noted that in the above specific embodiment as illustrated in FIG. 9, the above sub-steps S231a and 232b are illustrated as an example only. There can be no specific order for mixing the components for the polyacrylamide (PAMA) layer and the polymethyl methacrylate (PMMA) layer.

Although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A packaging assembly for packaging a display component over a substrate, comprising a first super absorbent polymer layer, wherein:
the first super absorbent polymer layer covers the display component; and
the first super absorbent polymer layer is configured to absorb water from the display component to thereby ensure a waterproofness thereof.

2. The packaging assembly of claim 1, wherein the first super absorbent polymer layer is included in a first packaging sub-assembly, wherein the first packaging sub-assembly further comprises a first inorganic film layer, a first organic film layer, and a second organic film layer, wherein:
the first inorganic film layer covers the outside of the display component;
the first organic film layer covers an outside of the first inorganic film layer;
the first super absorbent polymer layer covers an outside of the first organic film layer; and
the second organic film layer covers an outside of the first super absorbent polymer layer.

3. The packaging assembly of claim 2, further comprising a second inorganic film layer over the first packaging sub-assembly.

4. The packaging assembly of claim 2, further comprising a second packaging sub-assembly over the first packaging sub-assembly, wherein the second packaging sub-assembly comprises a second inorganic film layer, a third organic film layer, a second super absorbent polymer layer, and a fourth organic film layer, wherein:
the second inorganic film layer covers an outside of the second organic film layer;
the third organic film layer covers an outside of the second inorganic film layer;
the second super absorbent polymer layer covers an outside of the third organic film layer; and
the fourth organic film layer covers an outside of the second super absorbent polymer layer.

5. The packaging assembly of claim 2, further comprising at least one second inorganic film layer and at least one third organic film layer, alternately over the first packaging sub-assembly.

6. The packaging assembly of claim 5, wherein the first super absorbent polymer layer comprises at least one of a starch-type super absorbent polymer, a cellulose-type super absorbent polymer, or a synthetic-type super absorbent polymer.

7. The packaging assembly of claim 6, wherein the first super absorbent polymer layer comprises a synthetic-type super absorbent polymer, wherein the synthetic-type super absorbent polymer is polyacrylamide polymer (PAMA).

8. The packaging assembly of claim 6, wherein the first super absorbent polymer layer comprises at least one of a starch-acrylonitrile polymer or a cellulose acrylonitrile polymer.

9. The packaging assembly of claim 8, wherein the second organic film layer comprises at least one of polymethyl methacrylate (PMMA) or polycarbonate (PC).

10. A display apparatus, comprising:
a substrate;
a display component over the substrate; and
a packaging assembly according to any one of claims 1-9, wherein the packaging assembly is arranged over, and configured to cover the display component.

11. The display apparatus of claim 10, wherein the display component comprises an OLED display component.

12. A method for manufacturing a packaging assembly, comprising:
providing a display component over a substrate; and
forming a first packaging sub-assembly over the display component, wherein the first packaging sub-assembly comprises a first super absorbent polymer layer arranged to cover the display component and configured to absorb water from the display component to thereby ensure a waterproofness thereof.

13. The method according to claim 12, wherein the first packaging sub-assembly further comprises a first inorganic film layer, a first organic film layer, and a second organic film layer, wherein the forming a first packaging sub-assembly over the display component comprises:
forming a first inorganic film layer over the display component;
forming a first organic film layer over the first inorganic film layer; and
forming the first super absorbent polymer layer and a second organic film layer sequentially over the first organic film layer.

14. The method according to claim 13, wherein the first packaging sub-assembly further comprises a first inorganic film layer, a first organic film layer, and a second organic film layer, wherein the forming a first packaging sub-assembly over the display component comprises:
preparing a mixture solution comprising first components for synthesizing the first super absorbent polymer layer and second components for synthesizing the second organic film layer;
coating the mixture solution over the first organic film layer;
applying a first reaction condition to the mixture solution such that the first super absorbent polymer layer is formed over the first organic film layer; and
applying a second reaction condition to the mixture solution such that the second organic film layer is formed over the first super absorbent polymer layer.

15. The method according to claim 14, wherein in the preparing a mixture solution comprising first components for synthesizing the first super absorbent polymer layer and second components for synthesizing the second organic film layer, the first components for synthesizing the first super absorbent polymer layer comprise acrylamide (AM), 2-acrylamide-2-methyl propane sulfonic acid (AMPS), N, N′-methylene diacrylamide (NMBA), and potassium persulfate (KPS).

16. The method according to claim 15, wherein:
in the preparing a mixture solution comprising first components for synthesizing the first super absorbent polymer layer and second components for synthesizing the second organic film layer, a mass ratio of acrylamide (AM), 2-acrylamide-2-methyl propane sulfonic acid (AMPS), and N, N′-methylene diacrylamide (NMBA) in the mixture solution is around 25:75:0.01; and
in the applying a first reaction condition to the mixture solution such that the first super absorbent polymer layer is formed over the first organic film layer, the first reaction condition comprises a pH of around 2.0, a temperature of around 40±5° C.

17. The method according to claim 16, wherein in the applying a first reaction condition to the mixture solution such that the first super absorbent polymer layer is formed over the first organic film layer, the first reaction condition further comprises an induction condition comprising at least one of ultrasonic induction, photonic induction, or chemical induction.

18. The method according to claim 15, wherein in the preparing a mixture solution comprising first components for synthesizing the first super absorbent polymer layer and second components for synthesizing the second organic film layer, the second components for synthesizing the second organic film layer comprise methyl methacrylate and azobisisobutyronitrile (AIBN).

19. The method according to claim 18, wherein:
in the preparing a mixture solution comprising first components for synthesizing the first super absorbent polymer layer and second components for synthesizing the second organic film layer, a mass ratio of methyl methacrylate and azobisisobutyronitrile (AIBN) in the mixture solution is around 99.5:0.5; and
in the applying a second reaction condition to the mixture solution such that the second organic film layer is formed over the first super absorbent polymer layer, the second reaction condition comprises a pH of around 7.0 and a temperature of around 70-80° C.

20. The method according to claim 13, wherein the forming the first super absorbent polymer layer and a second organic film layer sequentially over the first organic film layer comprises:
forming the first super absorbent polymer layer over the first organic film layer; and
forming the second organic film layer sequentially over the first super absorbent polymer layer.
